(19) United States
(12) Patent Application Publication
(10) Pub. No.: US 2025/0218874 A1
(43) Pub. Date: Jul. 3, 2025

(54) ANALYSIS METHOD FOR SEMICONDUCTOR DEVICE, AND ANALYSIS DEVICE THEREFOR

(71) Applicant: Dongguk University Industry-Academic Cooperation Foundation, Seoul (KR)

(72) Inventors: Kwunbum CHUNG, Seoul (KR); Kwangsik JEONG, Seoul (KR); Hyunmin HONG, Hwaseong-si (KR)

(73) Assignee: Dongguk University Industry-Academic Cooperation Foundation, Seoul (KR)

(21) Appl. No.: 18/850,829

(22) PCT Filed: Apr. 3, 2023
(86) PCT No.: PCT/KR2023/004467

§ 371 Date: Sep. 25, 2024

(30) Foreign Application Priority Data
Apr. 6, 2022 (KR) 10-2022-0043071

(51) Int. Cl. H01L 21/66

(52) U.S. Cl. CPC H01L 22/14

(57) ABSTRACT

Disclosed in the present invention is an analysis method for a semiconductor device, and an analysis device therefor, the analysis method comprising: manufacturing a semiconductor device; supplying a first optical signal to the semiconductor device; detecting a second optical signal reflected from the semiconductor device; and determining pass or fail for the semiconductor device by analyzing the second optical signal, wherein the determination of the pass or fail for the semiconductor device by analyzing the second optical signal comprises: measuring an electrical characteristic of the semiconductor device; correlating the electrical characteristic with the second optical signal; and determining pass or fail for the semiconductor device from the electrical characteristic, and the electrical characteristic is a threshold voltage of the semiconductor device.

### TECHNICAL FIELD

The present invention relates to an analysis method for a semiconductor device and an analysis device therefor, and more particularly, to an analysis method for a semiconductor device using a nonlinear optical signal and an analysis device therefor.

### BACKGROUND ART

In nonlinear optics, light input(s) are output at the sum, a difference, or harmonic frequencies of the input(s). Second harmonic generation SHG is a nonlinear effect in which light is emitted with a frequency twice that of incident light beam. This process may be considered as coupling two photons of energy E to produce a single photon 2E (i.e., produce light of twice a frequency 2ω or half a wavelength). This effect may also be generalized to the coupling of photons having different energies corresponding to different frequencies.

Without following any specific theory, an SHG process does not occur within or in a bulk of materials exhibiting a center of symmetry (i.e., inversion or centrosymmetric materials). For these materials, the SHG process may be detected only at a surface and/or interface on which the inversion symmetry of the bulk material is broken. Therefore, the SHG process provides sensitive information about surface and interface properties.

As a result, the SHG effect may be useful for detecting the interface characteristics during wafer manufacturing in a deposition process such as chemical vapor deposition (CVD), atomic layer deposition (ALD), and sputtering. Therefore, SHG technologies may provide a unique non-contact wafer/substrate inspection opportunity.

### DISCLOSURE OF THE INVENTION

### Technical Problem

One technical object of the present invention is to provide an analysis method for a semiconductor device using a nonlinear optical signal and an analysis device therefor.

The problems to be solved by the present invention are not limited to the aforementioned technical objects and unmentioned technical objects will be clearly understood by those skilled in the art from the specification and the appended claims.

### Technical Solution

To solve the above technical problems, an analysis method for a semiconductor device according to embodiments of the present invention includes manufacturing a semiconductor device, supplying a first optical signal to the semiconductor device, detecting a second optical signal reflected from the semiconductor device, and determining pass/fail for the semiconductor device by analyzing the second optical signal, wherein the determining of the pass/fail for the semiconductor device by analyzing the second optical signal may include measuring an electrical characteristic of the semiconductor device, correlating the electrical characteristic with the second optical signal, and determining the pass or fail for the semiconductor device from the electrical characteristic, wherein the electrical characteristic may be a threshold voltage of the semiconductor device.

The analysis method may further include, when a result of the determination of the pass/fail for the semiconductor device is fail, modifying a manufacturing process condition of the semiconductor device.

The modifying of the manufacturing process condition of the semiconductor device may include modifying at least one of a composition of a material, a partial pressure of oxygen, plasma power, a pressure, a heat treatment atmosphere, or a heat treatment temperature during the manufacturing process.

The manufacturing of the semiconductor device may include: forming a gate electrode on a substrate, forming a gate insulating layer on the gate electrode, forming an oxide semiconductor layer on the gate insulating layer, and forming a source electrode and a drain electrode on the oxide semiconductor layer.

The manufacturing of the semiconductor device may further include forming a passivation layer on the oxide semiconductor layer, and performing a heat treatment process on the semiconductor device.

The oxide semiconductor layer may be formed between the gate electrode and the substrate.

The gate electrode may be formed between the oxide semiconductor layer and the substrate.

Each of the oxide semiconductor layer, the gate insulating layer, and the gate electrode may be formed in the form of a thin film.

The analysis method may further include, when a result of the determination of the pass/fail for the semiconductor device is fail, performing a subsequent process the semiconductor device.

The subsequent process may include supplying a third optical signal having a path or source different from that of the first optical signal to the semiconductor device.

A subsequent process may include changing the electrical characteristic of the semiconductor device.

A frequency of the second optical signal may be twice a frequency of the first optical signal.

The analysis method may further include storing information about the second optical signal in a database after the detecting of the second optical signal.

To solve the above technical problems, an analysis device according to embodiments of the present invention includes a light source part configured to emit a first optical signal, a sample part configured to receive the first optical signal and reflect the first optical signal into a second optical signal, a detection part configured to detect the second optical signal, and a analysis part configured to analyze a signal detected by the detection part, wherein the same part may be configured so that semiconductor devices are arranged on a substrate, the analysis part may be configured to determine pass/fail for each of the semiconductor devices, and a frequency of the second optical signal may be twice a frequency the first optical signal.

The light source part may include a first laser light source, and wherein the first laser light source may include a fs-laser.

The sample part may include a stage configured to move the substrate planarly.

The sample part may further include a half-waveplate between the light source part and the stage and at least one optical element between the stage and the detection part.

The analysis device may further include a subsequent process proceeding part configured to supply a third optical signal to the sample part, wherein the subsequent process proceeding part may include a second laser light source.

The determining of the pass/fail for each of the semiconductor devices may include measuring an electrical characteristic of the semiconductor device; correlating the second optical signal with the electrical characteristic, and determining pass/fail for each of the semiconductor devices from the electrical characteristic. The electrical characteristic may include a threshold voltage of each of the semiconductor devices.

To solve the above technical problems, an analysis method for a semiconductor device according to embodiments of the present invention includes performing an analysis for a first semiconductor device, performing an analysis for a second semiconductor device different from the first semiconductor device, and reflecting information about the first semiconductor device when performing the analysis for the second semiconductor device, wherein the performing of the analysis for each of the first and second semiconductor devices may include supplying a first optical signal to each of the first and second semiconductor devices, detecting a second optical signal reflected from each of the first and second semiconductor devices, and determining pass/fail for each of the first and second semiconductor devices by analyzing the second optical signal, wherein the determining of the pass/fail for the second semiconductor device may include using a correlation between the electrical characteristic and the second optical signal, which is measured for the first semiconductor device, wherein the electrical characteristic may be a threshold voltage of each of the semiconductor devices.

### Advantageous Effects

According to the analysis method for the semiconductor device according to the present invention, the electrical characteristics of the semiconductor device may be quantitatively analyzed by correlating the electrode characteristics of the semiconductor device with the intensity of the nonlinear signal.

In addition, in the analysis method for the semiconductor device according to the present invention, the performance of the semiconductor device may be improved by modifying the manufacturing process conditions of the semiconductor device or performing the subsequent process for the semiconductor device after determining the pass/fail for the semiconductor device.

### BRIEF DESCRIPTION OF THE DRAWINGS

FIG. 1 is a flowchart for explaining an analysis method for a semiconductor device according to embodiments of the present invention.

FIG. 2 is a schematic view of an analysis device for the analysis method for the semiconductor device according to embodiments of the present invention.

FIG. 3 is a flowchart for explaining a method for manufacturing the semiconductor device in the analysis method for the semiconductor device according to embodiments of the present invention.

FIG. 4a is a plan view for explaining the semiconductor device that is an object to be analyzed in the analysis method for the semiconductor device according to embodiments of the present invention.

FIGS. 4b, 4c, and 4d are cross-sectional views for explaining the semiconductor device that is an object to be analyzed in the analysis method for the semiconductor device according to embodiments of the present invention, and each of FIGS. 4b, 4c, and 4d corresponds to a cross-section taken along line I-I′ of FIG. 4a.

FIG. 5a is a flowchart for explaining determination of pass/fail for the semiconductor device in the analysis method for the semiconductor device according to embodiments of the present invention.

FIG. 5b is a graph for explaining the determination of the pass/fail for the semiconductor device in the analysis method for the semiconductor device according to embodiments of the present invention.

FIGS. 6A, 6b, 6c, 7a, 7b, 8a, and 8b are graphs for explaining modification of manufacturing process conditions of the semiconductor device in the analysis method for the semiconductor device according to embodiments of the present invention.

FIG. 9 is a flowchart for explaining the analysis method for the semiconductor device according to embodiments of the present invention.

FIGS. 10a and 10b are schematic views of an analysis device for the analysis method for the semiconductor device according to embodiments of the present invention.

FIGS. 11a, 11b, 12a, 12b, 12c, 12d, 12e, and 12f are graphs for explaining results of performing subsequent processes on the semiconductor device in the analysis method for the semiconductor device according to embodiments of the present invention.

### MODE FOR CARRYING OUT THE INVENTION

Preferred embodiments of the present invention will be described with reference to the accompanying drawings so as to sufficiently understand constitutions and effects of the present invention.

The present invention is not limited to the embodiments disclosed below, but can be implemented in various forms and can be subject to various modifications and changes. Rather, these embodiments are provided only to disclose the present invention and let those skilled in the art fully know the scope of the present invention. For convenience of explanation in the attached drawings, the proportions of each component may be exaggerated or reduced.

In this specification, the technical terms are used only for explaining a specific embodiment while not limiting the present invention. Unless the terms used in this specification are differently defined, the terms may be construed as meanings that are commonly known to a person skilled in the art.

In this specification, the terms of a singular form may comprise plural forms unless specifically mentioned. The meaning of ‘comprises’ and/or ‘comprising’ specifies a component, a step, an operation and/or an element does not exclude other components, steps, operations and/or elements.

Also, although terms like a first, a second, and a third are used to describe various regions, direction, and shapes in this specification, the regions, the direction, and the shapes are not limited to these terms. These terms are used only to discriminate one region, direction, or shape from another region, direction, or shape. Therefore, a portion referred to as a first portion in one embodiment can be referred to as a second portion in another embodiment. An embodiment described and exemplified herein includes a complementary embodiment thereof. Like reference numerals refer to like elements throughout.

When it is mentioned in this specification that a component is provided ‘on’ another component, it includes a case in which a component is provided directly on (i.e., in direct contact with) a top surface of the other component, and a case in which a third component is interposed between the components.

Hereinafter, an analysis method for a semiconductor device and an analysis device therefor according to embodiments of the present invention will be described in detail with reference to the drawings.

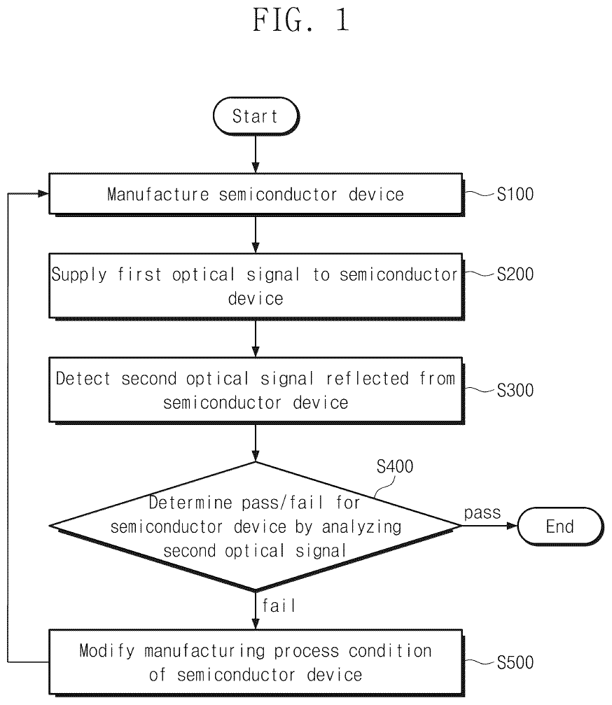

FIG. 1 is a flowchart for explaining an analysis method for a semiconductor device according to embodiments of the present invention.

Referring to FIG. 1, an analysis method for a semiconductor device according to the present invention may include manufacturing a semiconductor device (S100), supplying a first optical signal to the semiconductor device (S200), detecting a second optical signal reflected from the semiconductor device (S300), and analyzing the second optical signal to determine pass/fail for the semiconductor device (S400). According to embodiments, the analysis method for the semiconductor device according to the present invention may further include storing information about the second optical signal in a database after the detecting of the second optical signal (S300). According to embodiments, the analyzing of the second optical signal may include using the information stored in the database when analyzing another semiconductor device.

The analysis method for the semiconductor device according to the present invention may further include modifying the manufacturing process conditions of the semiconductor device when the result of the determination of the pass/fail for the semiconductor device is fail (S500). The modifying of the manufacturing process conditions of the semiconductor device (S500) may be modifying at least one of a composition of a material, a partial pressure of oxygen, plasma power, a pressure, a heat treatment atmosphere, or a heat treatment temperature during the manufacturing process.

The modifying of the manufacturing process conditions of the semiconductor device (S500) may be performed by repeatedly performing processes including the manufacturing of the semiconductor device (S100), the supplying of the first optical signal to the semiconductor device (S200), the detecting of the second optical signal reflected from the semiconductor device (S300), and the analyzing of the second optical signal to determine the pass/fail for the semiconductor device (S400). This repetitive processes may be continue until the result of the determination of the pass/fail for the semiconductor device is pass.

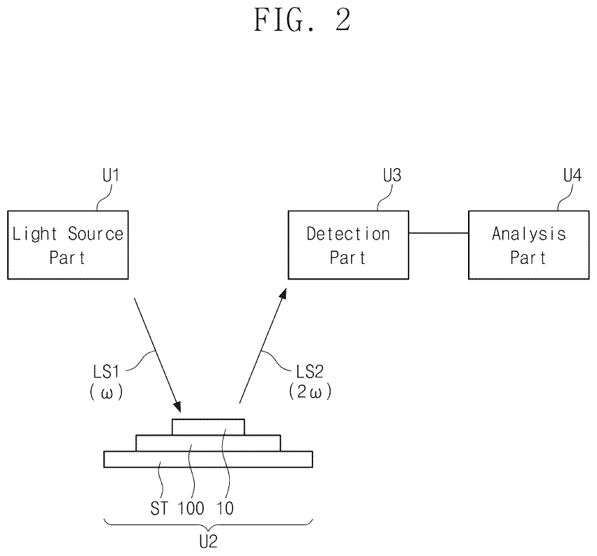

FIG. 2 is a schematic view of the analysis device for the analysis method for the semiconductor device according to embodiments of the present invention.

Referring to FIG. 2, the analysis device according to the present invention may include a light source part U1, a sample part U2, a detection part U3, and an analysis part U4.

The light source part U1 may be configured to emit a first optical signal LS1. The light source part U1 may include a first laser light source, and the first laser light source may be a femtosecond (fs)-laser.

The sample part U2 may be configured to receive the first optical signal LS1 and reflect the first optical signal LS1 into a second optical signal LS2. A frequency 2ω of the second optical signal LS2 may be twice a frequency ω of the first optical signal LS1. That is, the second optical signal LS2 may be a second harmonic generation (SHG) signal for the first optical signal LS1.

The sample part U2 may be configured so that semiconductor devices 10 are arranged on a substrate 100. The sample part U2 may include a stage ST configured to move the substrate 100 planarly. As described below with reference to FIG. 10a or FIG. 10b, the sample part U2 may further include a half-waveplate between the light source part U1 and the stage ST and at least one optical element between the stage ST and the detection part U3. The optical element may be, for example, one of a bandpass filter, a short pass filter, and a dichromatic mirror.

Each of the semiconductor devices 10 that are objects to be analyzed in the analysis device according to the present invention may be a transistor element including an oxide semiconductor material or a thin film structure including an oxide semiconductor thin layer, but the present invention is not limited thereto.

The detection part U3 may be configured to detect the second optical signal LS2, and the analysis part U4 may be configured to analyze a signal detected by the detection part U3. More specifically, the analysis part U4 may be configured to determine pass/fail for each of the semiconductor devices 10. According to embodiments, the analysis part U4 may further include a control module configured to modify manufacturing process conditions of the semiconductor devices 10.

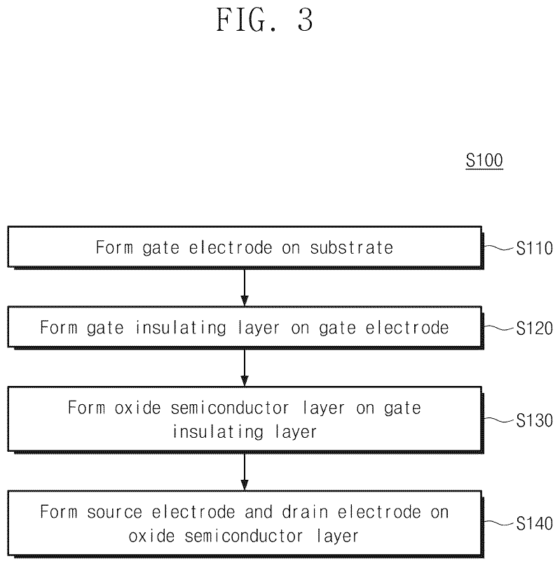

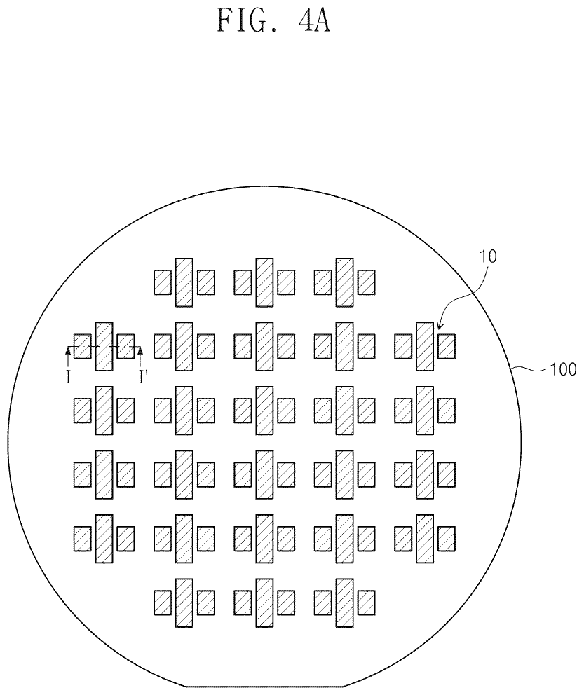

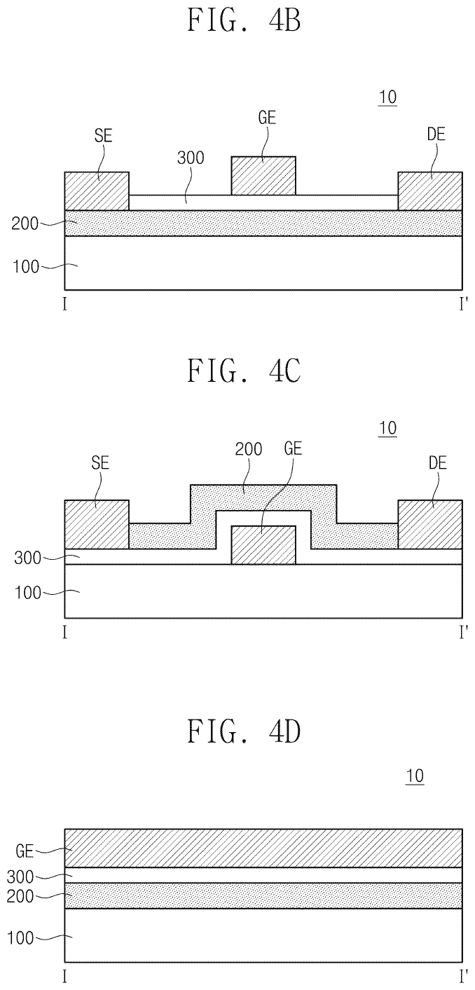

FIG. 3 is a flowchart for explaining a method for manufacturing the semiconductor device in the analysis method for the semiconductor device according to embodiments of the present invention. FIG. 4a is a plan view for explaining the semiconductor device that is an object to be analyzed in the analysis method for the semiconductor device according to embodiments of the present invention. FIGS. 4b, 4c, and 4d are cross-sectional views for explaining the semiconductor device that is an object to be analyzed in the analysis method for the semiconductor device according to embodiments of the present invention, and each of FIGS. 4b, 4c, and 4d corresponds to a cross-section taken along line I-I′ of FIG. 4a.

Referring to FIGS. 3 and 4a to 4d, the manufacturing of the semiconductor device 10 (S100) may include forming a gate electrode GE on the substrate 100 (S110), forming a gate insulating layer 300 on the gate electrode GE (120), forming an oxide semiconductor layer 200 on the gate insulating layer 300 (S130), and forming a source electrode SE and a drain electrode DE on the oxide semiconductor layer 200 (S140). However, the formation order of the gate electrode GE, the gate insulating layer 300, the oxide semiconductor layer 200, and the source/drain electrodes SE and DE is not limited to that described above.

According to embodiments, the manufacturing of the semiconductor device 10 (S100) may further include forming a passivation layer on the oxide semiconductor layer 200 and performing a heat treatment process on the semiconductor device 10. The passivation layer may cover top surfaces of the source/drain electrodes SE and DE or a top surface of the gate electrode GE.

Referring to FIG. 4a, the substrate 100 on which the plurality of semiconductor devices 10 are arranged may be a semiconductor substrate including at least one of silicon, germanium, and silicon-germanium, a compound semiconductor substrate, a glass substrate, or a plastic substrate. For example, the semiconductor substrate 100 may be a silicon wafer. According to embodiments, the semiconductor device 10 may be formed within a front-end-of-line (FEOL) layer on the substrate 100, within a back-end-of-line (BEO) layer, or within a peripheral circuit structure.

Referring to FIGS. 4a and 4b, the semiconductor device 10 may include an oxide semiconductor layer 200, a gate insulating layer 300, a gate electrode GE, and source/drain electrodes SE and DE, which are sequentially stacked on the substrate 100. The oxide semiconductor layer 200 may be formed between the gate electrode GE and the substrate 100. In other words, the semiconductor device 10 may be a transistor having a top-gate structure. According to an embodiment, the source/drain electrodes SE and DE may be provided between the substrate 100 and the oxide semiconductor layer 200. According to another embodiment, the source/drain electrodes SE and DE may be provided between the oxide semiconductor layer 200 and the gate insulating layer 300.

The oxide semiconductor layer 200 may be made of a compound of oxygen (O) and at least two elements selected from the group consisting of, for example, hydrogen (H), zinc (Zn), indium (In), gallium (Ga), tin (Sn), tantalum (Ta), strontium (Sr), titanium (Ti), copper (Cu), rhodium (Rh), and aluminum (Al). The gate insulating layer 300 may include, for example, at least one of silicon oxide, silicon nitride, silicon oxynitride, or a high-k dielectric material. The high-k dielectric material may be a material having a higher dielectric constant than each of silicon oxide and silicon nitride, such as hafnium oxide, aluminum oxide, or tantalum oxide. Each of the gate electrode GE and the source/drain electrodes SE and DE may include at least one of, for example, a doped semiconductor material (doped silicon, doped germanium, etc.), a conductive metal nitride (titanium nitride, tantalum nitride, tungsten nitride, etc.), or a metal material (titanium, tantalum, tungsten, copper, aluminum, ruthenium, molybdenum, etc.).

Referring to FIGS. 4a and 4c, the semiconductor device 10 may include a gate electrode GE on the substrate 100, a gate insulating layer 300 covering the gate electrode GE and the substrate 100, an oxide semiconductor layer 200 on the gate insulating layer 300, and source/drain electrodes SE and DE on the gate insulating layer 300. The gate electrode GE may be formed between the oxide semiconductor layer 200 and the substrate 100. In other words, the semiconductor device 10 may be a transistor having a bottom-gate structure. According to an embodiment, the source/drain electrodes SE and DE may be provided on a top surface of the oxide semiconductor layer 200. According to another embodiment, the source/drain electrodes SE and DE may be provided between the gate insulating layer 300 and the oxide semiconductor layer 200.

Referring to FIGS. 4a and 4c, the semiconductor device 10 may include an oxide semiconductor layer 200, a gate insulating layer 300, and a gate electrode GE, which are sequentially stacked on the substrate 100. Each of the oxide semiconductor layer 200, the gate insulating layer 300, and the gate electrode GE on the substrate 100 may be formed in the form of a thin film.

Referring again to FIG. 2 together with FIGS. 4a to 4d, when the first optical signal LS1 is supplied to the semiconductor device 10, the second optical signal LS2 may be generated by electric fields at an interface between the gate insulating layer 300 and the oxide semiconductor layer 200. Here, the second optical signal LS2 may be a nonlinear signal having energy that is an integer multiple of an initial photon, which is generated by the electric fields at the interface between the gate insulating layer 300 and the oxide semiconductor layer 200.

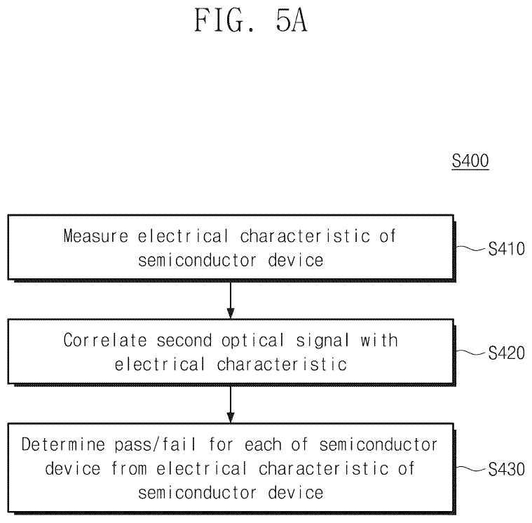

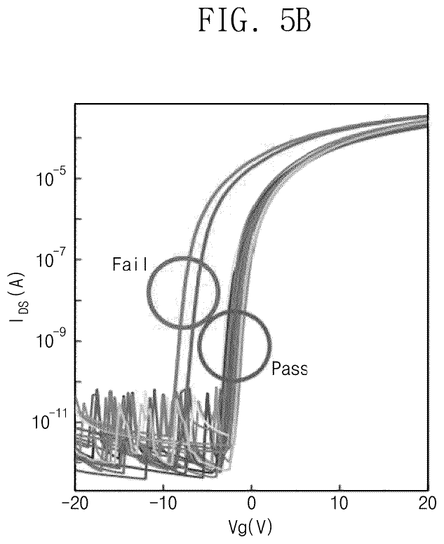

FIG. 5a is a flowchart for explaining determination of pass/fail for the semiconductor device in the analysis method for the semiconductor device according to embodiments of the present invention.

Referring to FIG. 5a, the determining of the pass/fail for the semiconductor device (S400) may include measuring electrical characteristics of the semiconductor device (S410), correlating the second optical signal with the electrical characteristics (S420), and determining the pass/fail for the semiconductor device from the electrical characteristics of the semiconductor device (S430). Here, the electrical characteristic may be a threshold voltage Vₜₕ of the semiconductor device.

According to embodiments, the analysis method for the semiconductor device according to the present invention may further include storing information about the second optical signal in the database after the detecting of the second optical signal (S300). Here, the information about the second optical signal may include information about a correlation between the second optical signal and the electrical characteristics.

For example, the threshold voltage may be defined as a gate voltage V_{g} at which an inclination of an I-V graph becomes maximum (i.e., drain current I_{DS} increases rapidly). As another example, the threshold voltage may be defined as an intercept of a tangent line on the I-V graph at a point at which the inclination is maximum. As another example, the threshold voltage may be defined as a gate voltage V_{g} corresponding to a predetermined value of the drain current I_{DS}.

FIG. 5b is a graph for explaining the determination of the pass/fail for the semiconductor device in the analysis method for the semiconductor device according to embodiments of the present invention. More specifically, FIG. 5b is a result of measuring the electrical characteristics of the plurality of semiconductor devices arranged in an array form as in FIG. 4a. In FIG. 5b, a horizontal axis represents the gate voltage V_{g} (unit: V), and a vertical axis represents the drain current I_{DS} (unit: A).

Referring to FIG. 5b, the semiconductor device, of which the measured threshold voltage is less than a reference value may be determined as ‘fail’. The reference value may be determined in advance based on requirements for accuracy and performance of the semiconductor device to be measured. For example, the semiconductor devices in which the measured threshold voltage and the reference value have a difference of more than about 5 V may be determined as ‘fail’. Preferably, the semiconductor devices in which the measured threshold voltage and the reference value have a difference greater than about 3 V may be determined as ‘fail’. More preferably, the semiconductor devices in which the measured threshold voltage and the reference value have a difference greater than about 1 V may be determined as ‘fail’.

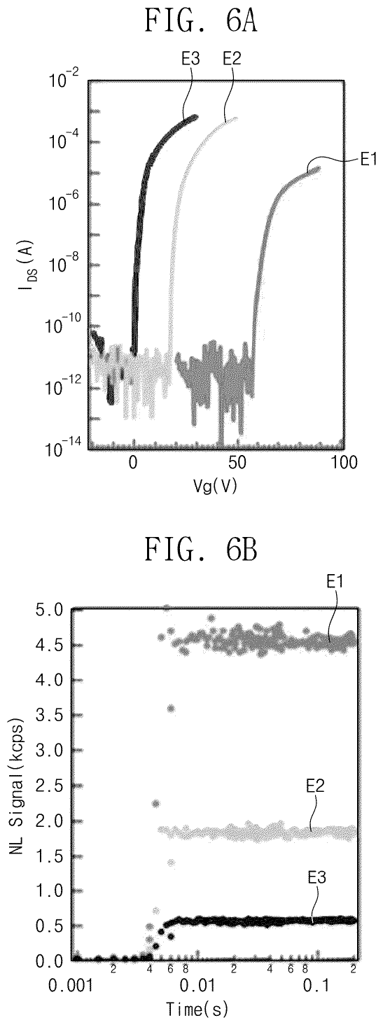

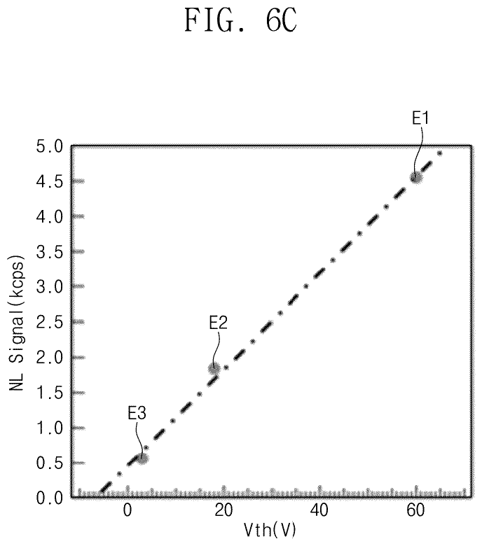

FIGS. 6a, 6b, and 6c are graphs for explaining the modification of the manufacturing process conditions of the semiconductor device in the analysis method for the semiconductor device according to embodiments of the present invention. More specifically, FIG. 6a is a graph illustrating a change in threshold voltage according to a partial pressure of oxygen during the deposition of the oxide semiconductor layer, FIG. 6b is a graph illustrating a change in intensity of the nonlinear signal (NL signal) according to the partial pressure of oxygen during the deposition of the oxide semiconductor layer, and FIG. 6c is a graph for explaining a relationship between the threshold voltage and the intensity of the nonlinear signal. In FIG. 6a, a horizontal axis represents the gate voltage V_{g} (unit: V), and a vertical axis represents the drain current I_{DS} (unit: A). In FIG. 6b, a horizontal axis represents a time (unit: seconds(s)), and a vertical axis represents an intensity (unit: kcps) of the nonlinear signal. In FIG. 6c, a horizontal axis represents the threshold voltage Vₜₕ (unit: V), and a vertical axis represents the intensity (unit: kcps) of the nonlinear signal.

Referring to FIGS. 6a to 6c, a (1-1)-th experimental example E1 is a case in which the partial pressure of oxygen is about 60% during the deposition of the oxide semiconductor layer, a (1-2)-th experimental example E2 is a case in which the partial pressure of oxygen is about 10% during the deposition of the oxide semiconductor layer, and a (1-3)-th experimental example E3 is a case in which the partial pressure of oxygen is about 0% during the deposition of the oxide semiconductor layer.

Referring to FIGS. 6a and 6b, the threshold voltage and the intensity of the nonlinear signal in the (1-1)-th experimental example E1 may be greater than that of each of the (1-2)-th experimental example E2 and the (1-3)-th experimental example E3. A threshold voltage and an intensity of the nonlinear signal in the (1-2)-th experimental example E2 may be greater than those in the (1-3)-th experimental example E3.

Referring to FIG. 6c, the measured threshold voltage and the intensity of the nonlinear signal may be proportional to each other as the partial pressure of oxygen is changed during the deposition of the oxide semiconductor layer. Due to this relationship, the electrical characteristics (i.e., the threshold voltage) of the semiconductor device may be measured (or predicted) through the intensity of the nonlinear signal, and the intensity of the nonlinear signal may be measured (or predicted) through the electrical characteristics of the semiconductor device. The proportional relationship between the threshold voltage and the intensity of the nonlinear signal may be attributed to the change in the interfacial electric fields due to the change in carrier concentration and a defect density in the gate insulating layer and the oxide semiconductor layer.

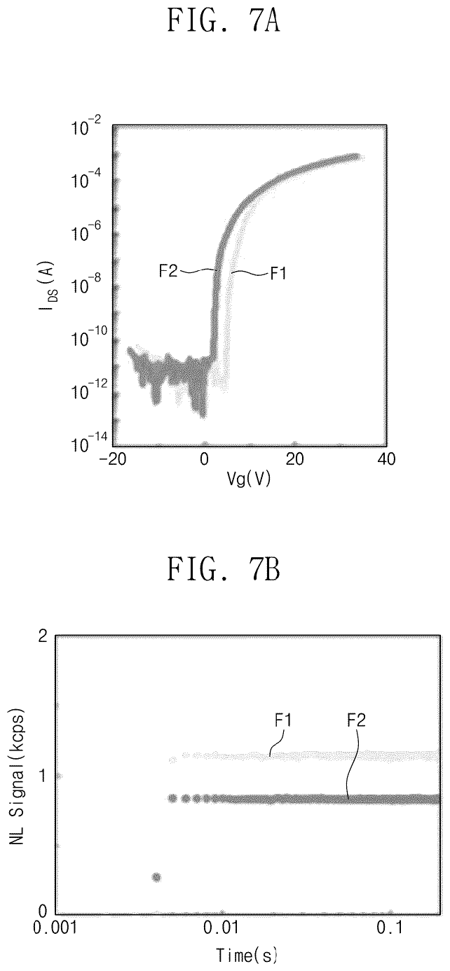

FIGS. 7a and 7b are graphs for explaining the modifying of the manufacturing process conditions of the semiconductor device in the analysis method for the semiconductor device according to embodiments of the present invention. More specifically, FIG. 7a is a graph illustrating a change in threshold voltage according to the atmosphere of the heat treatment process for the oxide semiconductor layer, and FIG. 7b is a graph illustrating a change in intensity of the nonlinear signal according to the atmosphere of the heat treatment process for the oxide semiconductor layer. In FIG. 7a, a horizontal axis represents the gate voltage V_{g} (unit: V), and a vertical axis represents the drain current I_{DS} (unit: A). In FIG. 7b, a horizontal axis represents a time (unit: seconds(s)), and a vertical axis represents an intensity (unit: kcps) of the nonlinear signal.

Referring to FIGS. 7a and 7b, a (2-1)-th experimental example F1 is a case in which the heat treatment process for the oxide semiconductor layer is performed at a temperature of about 350 degrees in air with a partial pressure of oxygen at about 0%, and a (2-2)-th experimental example F2 is a case in which the heat treatment process for the oxide semiconductor layer is performed at a temperature of about 350 degrees in a vacuum with a partial pressure of oxygen at about 0%. Here, the threshold voltage and the intensity of the nonlinear signal of (2-1)-th experimental example F1 may be greater than those of the (2-2)-th experimental example F2.

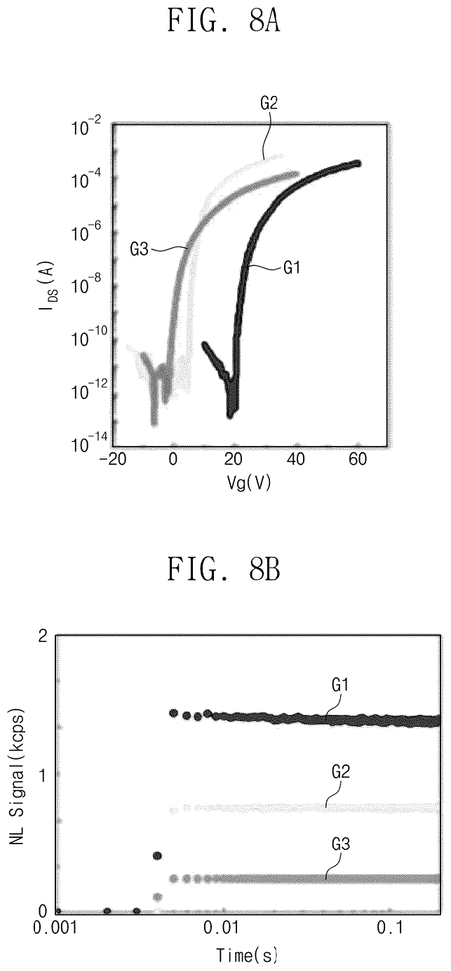

FIGS. 8A and 8B are graphs for explaining the modification of the manufacturing process conditions of the semiconductor device in the analysis method for the semiconductor device according to embodiments of the present invention. More specifically, FIG. 7a is a graph illustrating a change in threshold voltage according to the temperature of the heat treatment process for the oxide semiconductor layer, and FIG. 7b is a graph illustrating a change in intensity of the nonlinear signal according to the temperature of the heat treatment process for the oxide semiconductor layer. In FIG. 8a, a horizontal axis represents the gate voltage V_{g} (unit: V), and a vertical axis represents the drain current I_{DS} (unit: A). In FIG. 8b, a horizontal axis represents a time (unit: seconds(s)), and a vertical axis represents an intensity (unit: kcps) of the nonlinear signal.

Referring to FIGS. 8a and 8b, a (3-1)-th experimental example G1 is a case in which the temperature of the heat treatment process for the oxide semiconductor layer is about 200 degrees, a (3-2)-th experimental example G2 is a case in which the temperature of the heat treatment process for the oxide semiconductor layer is about 350 degrees, and a (3-3)-th experimental example G3 is a case in which the temperature of the heat treatment process for the oxide semiconductor layer is about 500 degrees. In the (3-1)-th, (3-2)-th, and (3-3)-th experimental examples G1, G2, and G3, the atmosphere except for the temperature of the heat treatment process may be maintained substantially the same. Here, the threshold voltage and the intensity of the nonlinear signal of the (3-1)-th experimental example G1 may be greater than those of each of the (3-2)-th experimental example G2 and the (3-3)-th experimental example G3. A threshold voltage and an intensity of the nonlinear signal in the (3-2)-th experimental example G2 may be greater than those in the (3-3)-th experimental example G3.

Referring to FIGS. 6a, 6b, 6c, 7a, 7b, 8a, and 8b, the electrical characteristics (i.e., the threshold voltage) and the intensity of the nonlinear signal of the semiconductor device may be controlled by modifying the manufacturing process conditions of the semiconductor device (e.g., partial pressure of oxygen during the deposition of the oxide semiconductor layer, the atmosphere and temperature of the heat treatment process for the oxide semiconductor layer).

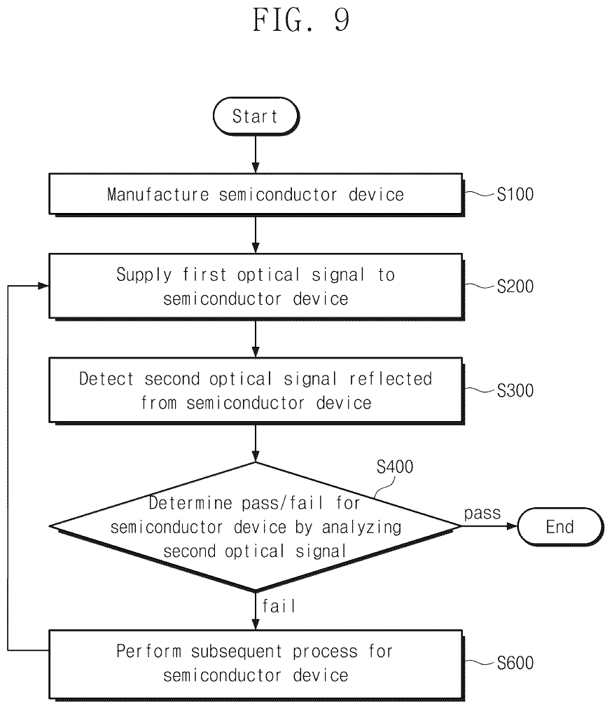

FIG. 9 is a flowchart for explaining the analysis method for the semiconductor device according to embodiments of the present invention. Hereinafter, for the convenience of explanation, the description of substantially the same matters as described by reference to FIG. 1 will be omitted, and difference will be described in detail.

Referring to FIG. 9, an analysis method for a semiconductor device according to the present invention may include, after analyzing a second optical signal to determine pass/fail for a semiconductor device (S400), performing a subsequent process for the semiconductor device if the result of the determination of the pass/fail for the semiconductor device is fail (S600). The performing of the subsequent process for the semiconductor device (S600) may include planarly moving a stage on which the semiconductor device is provided to find the semiconductor device requiring the subsequent process and supplying a third optical signal having a path or source different from that of the first optical signal to the semiconductor device. The electrical characteristics of the semiconductor device may be changed (i.e. improved) by the subsequent process. According to the analysis method for the semiconductor device described with reference to FIG. 9, electrical characteristics of a specific semiconductor device may be selectively changed (i.e., improved) substrate on which the plurality of semiconductor devices are arranged.

A process including the supplying of the first optical signal to the semiconductor device (S200), the detecting of the second optical signal reflected from the semiconductor device (S300), and the analyzing of the second optical signal to determine the pass/fail for the semiconductor device (S400) after performing the subsequent process (S600) may be repeatedly performed. This repetitive processes may be continue until the result of the determination of the pass/fail for the semiconductor device is pass.

FIG. 10a is a schematic view of the analysis device for the analysis method for the semiconductor device according to embodiments of the present invention. Hereinafter, for the convenience of explanation, descriptions of matters that are substantially the same as those described with reference to FIG. 2 are omitted, and differences therebetween are described in detail.

Referring to FIG. 10a, a sample part U2 may be provided between a light source part U1 and a detection part U3. The sample part U2 may include a beam splitter 1101, a half-wave plate 1105, a lens 1107, a stage ST, and a bandpass filter 1109, which are disposed in a path connecting the light source part U1 to the detection part U3. The beam splitter 1101 may divide the laser light emitted from the light source U1 into two paths.

First light passing through the beam splitter 1101 may pass through the half-wave p late 1105, the lens 1107, the stage ST, and the bandpass filter 1109 to proceed toward the detection part U3. The first light may generate an SHG signal in the semiconductor device 10. The half-wave plate 1105 may circularly polarize the first light. The bandpass filter 1109 may block other signals so that only the SHG signal selectively proceeds to the detection part U3. According to embodiments, instead of the bandpass filter 1109, at least one optical element such as a short pass filter or a dichromatic mirror may be provided.

Second light reflected from the beam splitter 1101 may be reflected from the mirrors 1103 to travel toward the semiconductor device 10 on the stage ST. The second light may be used to perform the subsequent process (S600) on the semiconductor device described with reference to FIG. 9. In other words, the second light may change the electrical characteristics of the semiconductor device 10. The analysis device according to the present invention may further include at least one lens 1107 between one of the mirrors 1103 and the stage ST.

FIG. 10b is a schematic view of the analysis device for the analysis method for the semiconductor device according to embodiments of the present invention. Hereinafter, for convenience of explanation, descriptions of matters substantially the same as those described with reference to FIG. 2 and FIG. 10a will be omitted, and differences will be described in detail.

Referring to FIG. 10b, the analysis device according to the present invention may further include a subsequent process proceeding part U5 configured to supply a third optical signal to the sample part U2. The subsequent process proceeding part U5 may include a second laser light source 1111. The second laser light source 1111 may be an ultraviolet light source. The subsequent process proceeding part U5 may further include at least one lens 1107 between the second laser light source 1111 and the stage ST.

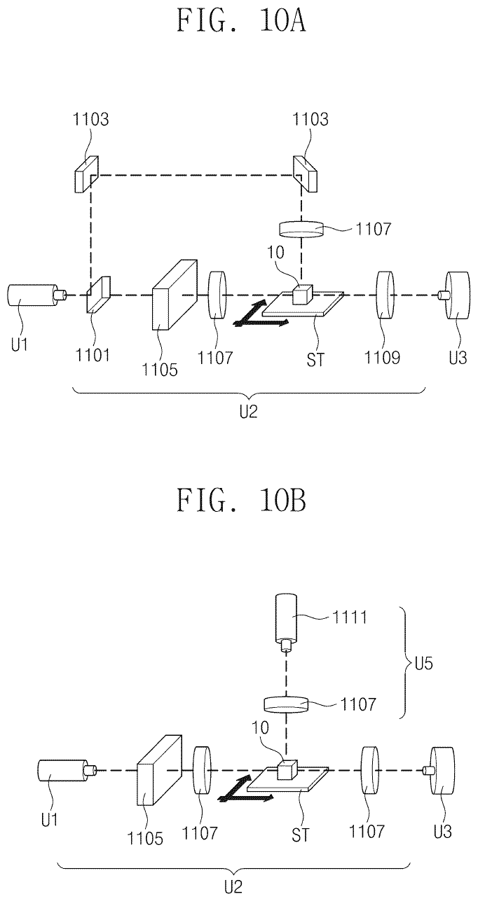

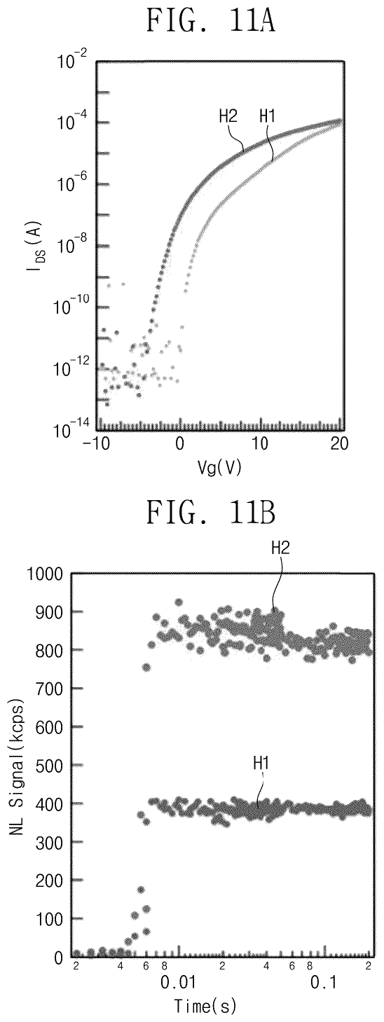

FIGS. 11a and 11b are graphs for explaining results of performing the subsequent process on the semiconductor device in the analysis method for the semiconductor device according to embodiments of the present invention. More specifically, FIG. 11a is a graph illustrating a change in threshold voltage before and after performing the subsequent process, and FIG. 11b is a graph illustrating a change in intensity of the nonlinear signal before and after performing the subsequent process. In FIG. 11a, a horizontal axis represents the gate voltage V_{g} (unit: V), and a vertical axis represents the drain current IDs (unit: A). In FIG. 11b, a horizontal axis represents a time (unit: seconds(s)), and a vertical axis represents an intensity (unit: kcps) of the nonlinear signal. In FIG. 6c, a horizontal axis represents the threshold voltage Vₜₕ (unit: V), and a vertical axis represents the intensity (unit: kcps) of the nonlinear signal.

Referring to FIGS. 11a and 11b, a (4-1)-th experimental example H1 is a case in which it is determined as ‘pass’, and a (4-2)-th experimental example H2 is a case in which it is determined as ‘fail’ after performing the subsequent process (i.e., laser light application) on the semiconductor device in the (4-1)-th experimental example H1. The (4-1)-th experimental example H1 may have a higher threshold voltage and a smaller nonlinear signal intensity than those in the (4-2)-th experimental example H2.

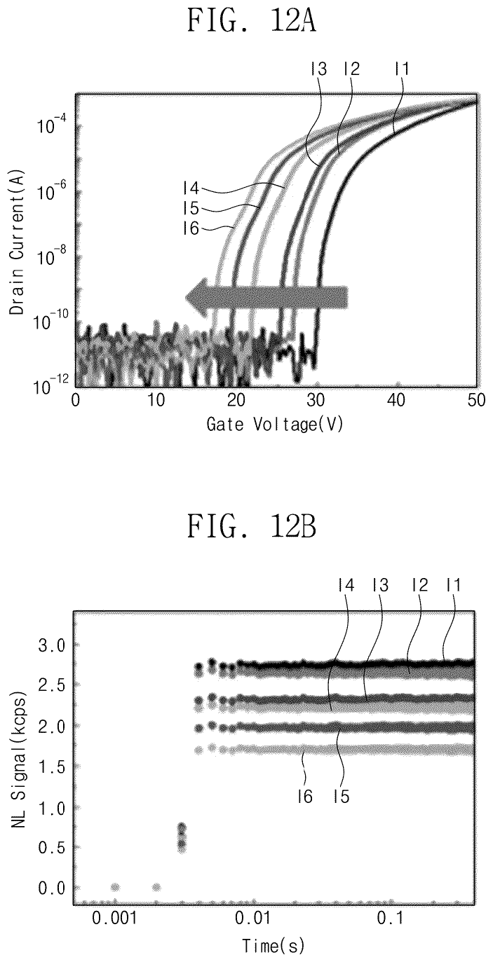

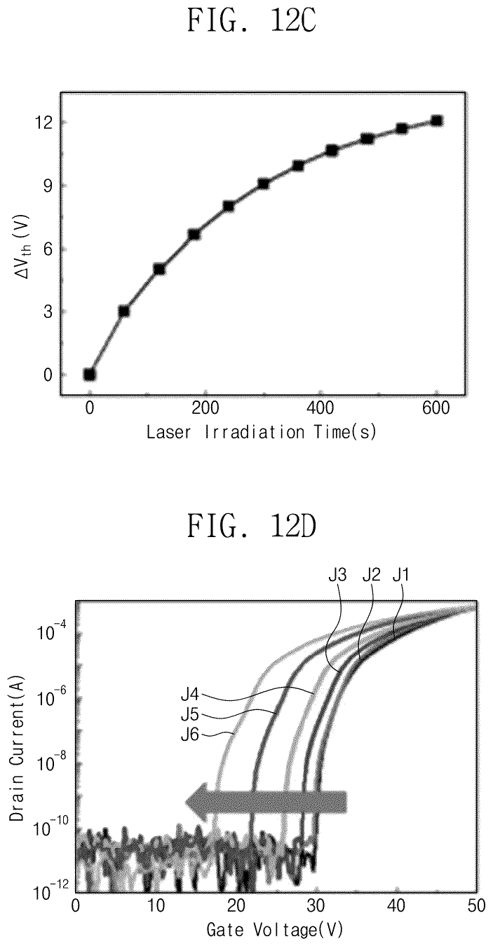

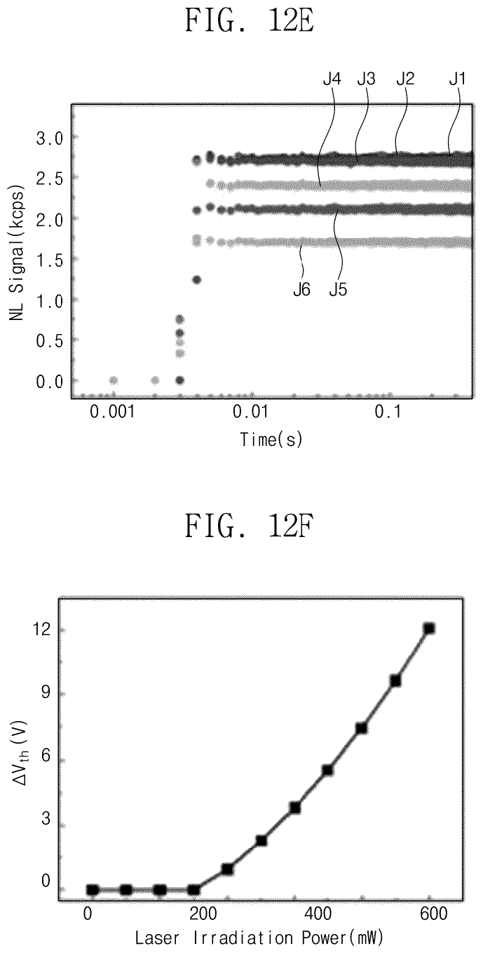

FIGS. 12a, 12b, 12c, 12d, 12e, and 12f are graphs for explaining results of performing the subsequent processes on the semiconductor device in the analysis method for the semiconductor device according to embodiments of the present invention. More specifically, FIGS. 12a, 12b, and 12c are graphs illustrating a change in threshold voltage depending on a progress time of each of the subsequent processes (i.e., a laser light incident time), a threshold voltage difference ΔVₜₕ compared to when the subsequent process is not performed, and a change in intensity of the nonlinear signal, respectively, and FIGS. 12d, 12e, and 12f are graphs illustrating a change in threshold voltage depending on power in the subsequent process (i.e., laser light power), a threshold voltage difference ΔVₜₕ compared to when the subsequent process is not performed, and a change in intensity of the nonlinear signal, respectively. In FIGS. 12a and 12d, a horizontal axis represents the gate voltage V_{g} (unit: V), and a vertical axis represents the drain current I_{DS} (unit: A). In FIGS. 12b and 12e, a horizontal axis represents a time (unit: seconds(s)), and a vertical axis represents an intensity (unit: kcps) of the nonlinear signal. In FIG. a horizontal axis represents a laser light incident time (unit: seconds(s)), and a vertical axis represents a threshold voltage difference ΔVₜₕ (unit: V) compared to when the subsequent process is not performed. In FIG. 12f, a horizontal axis represents power (unit: mW) of laser light, and a vertical axis represents a threshold voltage difference ΔVₜₕ (unit: V) compared to when the subsequent process is not performed.

Referring to FIGS. 12a, 12b, and 12c, (5-1)-th to (5-6)-th experimental examples I1 to I6 are cases where incident times of laser light are 0 seconds, 60 seconds, 120 seconds, 240 seconds, 480 seconds, and 600 seconds, respectively. A threshold voltage and an intensity of the nonlinear signal gradually decrease, and a threshold voltage difference ΔVₜₕ compared to when the subsequent process is not performed gradually increases from the (5-1)-th experimental example I1 to (5-6)-th experimental example I6 (i.e., as the incident time of the laser light increases). Here, the threshold voltage difference ΔVₜₕ compared to when the subsequent process is not performed may increase logarithmically.

Referring to FIGS. 12d, 12e, and 12f, (6-1)-th to (6-6)-th experimental examples J1 to J6 are cases in which the power of the laser light is 0 mW, 20 mW, 40 mW, 60 mW, 80 mW, and 100 mW, respectively. A threshold voltage and an intensity of the nonlinear signal gradually decrease, and a threshold voltage difference ΔVₜₕ compared to when the subsequent process is not performed gradually increases from the (6-1)-th experimental example J1 to (6-6)-th experimental example J6 (i.e., as the power of the laser light increases). Here, the threshold voltage difference ΔVₜₕ compared to when the subsequent process is not performed may increase exponentially.

Although the embodiments of the present invention is described with reference to the accompanying drawings, those with ordinary skill in the technical field of the present invention pertains will be understood that the present disclosure can be carried out in other specific forms without changing the technical idea or essential features. Therefore, the above-disclosed embodiments are to be considered illustrative and not restrictive.

1. An analysis method for a semiconductor device, comprising:
manufacturing a semiconductor device;
supplying a first optical signal to the semiconductor device;
detecting a second optical signal reflected from the semiconductor device; and
determining pass/fail for the semiconductor device by analyzing the second optical signal,
wherein the determining of the pass/fail for the semiconductor device by analyzing the second optical signal comprises:
measuring an electrical characteristic of the semiconductor device;
correlating the electrical characteristic with the second optical signal; and
determining of the pass/fail for the semiconductor device from the electrical characteristic,
wherein the electrical characteristic is a threshold voltage of the semiconductor device.

2. The analysis method of claim 1, further comprising, when a result of the determination of the pass/fail for the semiconductor device is fail, modifying a manufacturing process condition of the semiconductor device.

3. The analysis method of claim 2, wherein the modifying of the manufacturing process condition of the semiconductor device comprises modifying at least one of a composition of a material, a partial pressure of oxygen, plasma power, a pressure, a heat treatment atmosphere, or a heat treatment temperature during the manufacturing process.

4. The analysis method of claim 1, wherein the manufacturing of the semiconductor device comprises:
forming a gate electrode on a substrate;
forming a gate insulating layer on the gate electrode;
forming an oxide semiconductor layer on the gate insulating layer; and
forming a source electrode and a drain electrode on the oxide semiconductor layer.

5. The analysis method of claim 4, wherein the manufacturing of the semiconductor device further comprises:
forming a passivation layer on the oxide semiconductor layer; and
performing a heat treatment process on the semiconductor device.

6. The analysis method of claim 4, wherein the oxide semiconductor layer is formed between the gate electrode and the substrate.

7. The analysis method of claim 4, wherein the gate electrode is formed between the oxide semiconductor layer and the substrate.

8. The analysis method of claim 4, wherein each of the oxide semiconductor layer, the gate insulating layer, and the gate electrode is formed in the form of a thin film.

9. The analysis method of claim 1, further comprising, when a result of the determination of the pass/fail for the semiconductor device is fail, performing a subsequent process for the semiconductor device.

10. The analysis method of claim 9, wherein the subsequent process comprises supplying a third optical signal having a path or source different from that of the first optical signal to the semiconductor device.

11. The analysis method of claim 9, wherein the subsequent process comprises changing the electrical characteristic of the semiconductor device.

12. The analysis method of claim 1, wherein a frequency of the second optical signal is twice a frequency of the first optical signal.

13. The analysis method of claim 1, further comprising storing information about the second optical signal in a database after the detecting of the second optical signal.

14. An analysis device comprising:
a light source part configured to emit a first optical signal;
a sample part configured to receive the first optical signal and reflect the first optical signal into a second optical signal;
a detection part configured to detect the second optical signal; and
a analysis part configured to analyze a signal detected by the detection part,
wherein the sample part is configured so that semiconductor devices are arranged on a substrate,
the analysis part is configured to determine pass/fail for each of the semiconductor devices, and
a frequency of the second optical signal is twice a frequency the first optical signal.

15. The analysis device of claim 14, wherein the light source part comprises a first laser light source, and
wherein the first laser light source comprises a fs-laser.

16. The analysis device of claim 14, wherein the sample part comprises a stage configured to move the substrate planarly.

17. The analysis device of claim 16, wherein the sample part further comprises a half-waveplate between the light source part and the stage and at least one optical element between the stage and the detection part.

18. The analysis device of claim 14, further comprising a subsequent process proceeding part configured to supply a third optical signal to the sample part,
wherein the subsequent process proceeding part comprises a second laser light source.

19. The analysis device of claim 14, wherein the determining of the pass/fail for each of the semiconductor devices comprises:
measuring an electrical characteristic of each of the semiconductor devices;
correlating the second optical signal with the electrical characteristic; and
determining pass/fail for each of the semiconductor devices from the electrical characteristic,
wherein the electrical characteristic is a threshold voltage of each of the semiconductor devices.

20. An analysis method for a semiconductor device, comprising:
performing an analysis for a first semiconductor device;
performing an analysis for a second semiconductor device different from the first semiconductor device; and
reflecting information about the first semiconductor device when performing the analysis for the second semiconductor device,
wherein the performing of the analysis for each of the first and second semiconductor devices comprises:
supplying a first optical signal to each of the first and second semiconductor devices;
detecting a second optical signal reflected from each of the first and second semiconductor devices; and
determining pass/fail for each of the first and second semiconductor devices by analyzing the second optical signal,
wherein the determining of the pass/fail for the second semiconductor device comprises using a correlation between the electrical characteristic and the second optical signal, which is measured for the first semiconductor device,
wherein the electrical characteristic is a threshold voltage of the first semiconductor device.
